(19) United States
(12) Patent Application Publication
(10) Pub. No.: US 2024/0071817 A1
(43) Pub. Date: Feb. 29, 2024

(54) ADHESION IMPROVEMENT BETWEEN LOW-K MATERIALS AND CAP LAYERS

(71) Applicant: Applied Materials, Inc., Santa Clara, CA (US)

(72) Inventors: Ruitong Xiong, San Jose, CA (US); Rui Lu, Santa Clara, CA (US); Xiaobo Li, San Jose, CA (US); Bo Xie, San Jose, CA (US); Yijun Liu, Santa Clara, CA (US); Li-Qun Xia, Cupertino, CA (US)

(73) Assignee: Applied Materials, Inc., Santa Clara, CA (US)

(21) Appl. No.: 17/896,716

(22) Filed: Aug. 26, 2022

(51) Int. Cl. H01L 21/768; C23C 16/02; C23C 16/44; C23C 16/50; H01L 21/02

(52) U.S. Cl. CPC H01L 21/76829; C23C 16/0272; C23C 16/4408; C23C 16/50; H01L 21/02274; H01L 21/02337; H01L 21/02362

(57) ABSTRACT

Exemplary semiconductor processing methods may include providing one or more deposition precursors to a processing region of a semiconductor processing chamber. A semiconductor substrate may be positioned within the processing region. The methods may include forming a layer of low dielectric constant material on the semiconductor substrate. The methods may include purging the processing region of the one or more deposition precursors. A plasma power may be maintained at less than or about 750 W while purging the processing region. The methods may include forming an interface layer on the layer of low dielectric constant material. The methods may include forming a cap layer on the interface layer.

### TECHNICAL FIELD

The present technology relates to semiconductor processes and materials. More specifically, the present technology relates to improving adhesion between low dielectric constant materials and cap layers.

### BACKGROUND

Integrated circuits are made possible by processes which produce intricately patterned material layers on substrate surfaces. Producing patterned material on a substrate requires controlled methods for forming and removing material. Material characteristics may affect how the device operates, and may also affect how the films are removed relative to one another. Plasma-enhanced deposition may produce films having certain characteristics. Desirable characteristics in films may vary depending on their application.

Thus, there is a need for improved systems and methods that can be used to produce high quality devices and structures. These and other needs are addressed by the present technology.

### SUMMARY

Exemplary semiconductor processing methods may include providing one or more deposition precursors to a processing region of a semiconductor processing chamber. A semiconductor substrate may be positioned within the processing region. The methods may include forming a layer of low dielectric constant material on the semiconductor substrate. The methods may include purging the processing region of the one or more deposition precursors. A plasma power may be maintained at less than or about 750 W while purging the processing region. The methods may include forming an interface layer on the layer of low dielectric constant material. The methods may include forming a cap layer on the interface layer.

In some embodiments, the semiconductor substrate may be maintained at a temperature less than or about 550° C. during the semiconductor processing method. The methods may include purging the processing region of the one or more deposition precursors. A plasma power may be maintained at less than or about 750 W while purging the processing region. The methods may include halting a flow of the one or more deposition precursors prior to forming the interface layer. The methods may include providing an oxygen-containing precursor to the processing region prior to forming the interface layer. A flow rate of the oxygen-containing precursor may be less than or about 750 sccm. The methods may include densifying the layer of low dielectric constant material while purging the processing region of the one or more deposition precursors. An adhesion value between the layer of low dielectric constant material and the cap layer may be greater than or about 3.0 J/m².

Some embodiments of the present technology encompass semiconductor processing methods. The methods may include forming a layer of low dielectric constant material on a semiconductor substrate housed in a processing region of a semiconductor processing chamber. A plasma power may be maintained at a first plasma power level while forming the layer of low dielectric constant material. The methods may include purging the processing region. The plasma power may be maintained at a second plasma power level while purging the processing region. The second plasma power level may be less than or equal to the first plasma power level. The methods may include forming an interface layer on the layer of low dielectric constant material. The methods may include forming a cap layer on the interface layer.

In some embodiments, wherein the semiconductor substrate may include silicon. The layer of low dielectric constant material may be formed through plasma-enhanced chemical vapor deposition. The interface layer may be characterized by a lower methyl incorporation than the layer of low dielectric constant material. The methods may include providing molecular oxygen to the processing region while purging the processing region. The methods may include reducing a flow rate of one or more precursors used to form the layer of low dielectric constant material prior to purging the processing region. A temperature and a pressure in the processing region while forming the layer of low dielectric constant material may be maintained while forming the interface layer. The methods may include reducing a flow rate of a carrier gas prior to purging the processing region.

Some embodiments of the present technology encompass semiconductor structures. The structures may include a semiconductor substrate. The structures may include a layer of low dielectric constant material disposed on the semiconductor substrate. The structures may include a cap layer formed above the layer of low dielectric constant material. The structures may include an interface layer disposed between the layer of low dielectric constant material and the cap layer. An adhesion value between the layer of low dielectric constant material and the cap layer is greater than or about 4.0 J/m².

In some embodiments, the interface layer may be a portion of the layer of low dielectric constant material. The interface layer may be characterized by a lower methyl incorporation than the layer of low dielectric constant material. The interface layer may be characterized by a higher oxygen concentration than the layer of low dielectric constant material.

Such technology may provide numerous benefits over conventional systems and techniques. For example, the processes and structures may form an interface layer between the low dielectric constant material and the cap layer. Additionally, the formation of the interface layer may not substantially affect device performance while increasing adhesion between the low dielectric constant material and the cap layer. The increased adhesion may reduce and/or eliminate the possibility of the cap layer delaminating from the low dielectric constant material during subsequent processing. These and other embodiments, along with many of their advantages and features, are described in more detail in conjunction with the below description and attached figures.

### BRIEF DESCRIPTION OF THE DRAWINGS

A further understanding of the nature and advantages of the disclosed technology may be realized by reference to the remaining portions of the specification and the drawings.

FIG. 1 shows a top plan view of an exemplary processing system according to some embodiments of the present technology.

FIG. 2 shows a schematic cross-sectional view of an exemplary plasma system according to some embodiments of the present technology.

FIG. 3 shows selected operations in a formation method according to some embodiments of the present technology.

FIGS. 4A-4C show exemplary schematic cross-sectional structures in which material layers are included and produced according to some embodiments of the present technology.

Several of the figures are included as schematics. It is to be understood that the figures are for illustrative purposes, and are not to be considered of scale unless specifically stated to be of scale. Additionally, as schematics, the figures are provided to aid comprehension and may not include all aspects or information compared to realistic representations, and may include superfluous or exaggerated material for illustrative purposes.

In the appended figures, similar components and/or features may have the same reference label. Further, various components of the same type may be distinguished by following the reference label by a letter that distinguishes among the similar components. If only the first reference label is used in the specification, the description is applicable to any one of the similar components having the same first reference label irrespective of the letter.

### DETAILED DESCRIPTION

During back-end-of-line (BEOL) semiconductor processing, low dielectric constant films may serve multiple functions in the fabrication of metallization layers in an integrated circuit. These functions may include the incorporation of electrically-insulating low dielectric constant films between electrically-conductive metal-containing structures such as interconnect lines, contact holes, and vias, among other structures. They may also include the partial removal of a low dielectric constant film following the formation of metal structure. One common removal process in BEOL processing is chemical-mechanical-polishing (CMP) that uses a combination of chemical etching and physical abrasion to remove the low-x material from a substrate surface. In some applications, cap layers may be formed over the low dielectric constant films to further protect the low dielectric constant films.

However, the cap layers may face a number of issues, which may be exacerbated with shrinking feature sizes. For example, cap layers may cause experience difficulty adhering to the underlying low dielectric constant material. Additionally, during BEOL processing, the cap layers may delaminate and/or separate from the low dielectric films. Because of these and other issues, conventional technologies have been limited in the ability to further reduce feature sizes or prevent delamination of the cap layers from the low dielectric constant films.

The present technology overcomes these issues by performing a post-deposition treatment of the low dielectric constant films. A number of operations, together or separately, may treat the deposited low dielectric constant films to form an interface layer, which may be a part of the low dielectric constant films, that more readily adheres to the cap layer. Additionally, the treatment may be performed in the same chamber as the deposition, avoiding the need to break vacuum or expose the structure to atmosphere. Finally, the treatment may not materially affect the underlying low dielectric constant films, thereby maintaining integrity of the previously-formed structures.

Although the remaining disclosure will routinely identify specific deposition processes and post-deposition treatments utilizing the disclosed technology, and will describe one type of semiconductor processing chamber, it will be readily understood that the processes described are equally applicable to other deposition chambers, as well as processes that may be performed in any number of semiconductor processing chambers. Accordingly, the technology should not be considered to be so limited as for use with these specific deposition processes or chambers alone. The disclosure will discuss one possible chamber that may be used to perform processes according to embodiments of the present technology before methods of semiconductor processing according to the present technology are described.

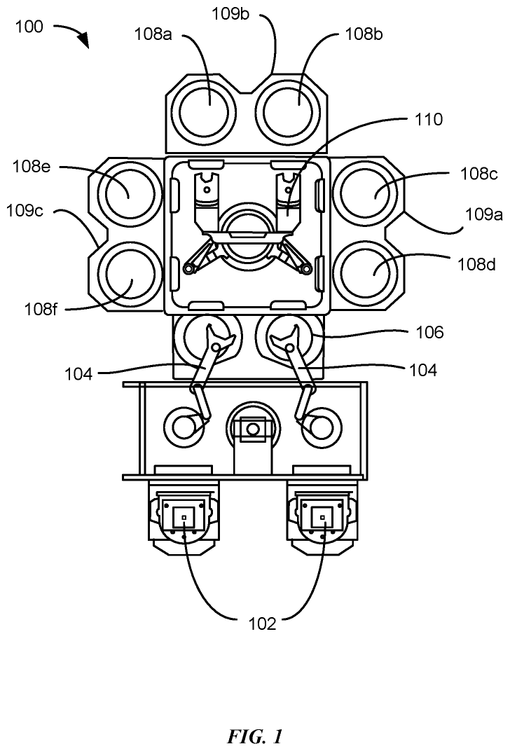

FIG. 1 shows a top plan view of one embodiment of a processing system 100 of deposition, etching, baking, and curing chambers according to embodiments. In the figure, a pair of front opening unified pods 102 supply substrates of a variety of sizes that are received by robotic arms 104 and placed into a low pressure holding area 106 before being placed into one of the substrate processing chambers 108a-f, positioned in tandem sections 109a-c. A second robotic arm 110 may be used to transport the substrate wafers from the holding area 106 to the substrate processing chambers 108a-f and back. Each substrate processing chamber 108a-f, can be outfitted to perform a number of substrate processing operations including formation of stacks of semiconductor materials described herein in addition to plasma-enhanced chemical vapor deposition, atomic layer deposition, physical vapor deposition, etch, pre-clean, degas, orientation, and other substrate processes including, annealing, ashing, etc.

The substrate processing chambers 108a-f may include one or more system components for depositing, annealing, curing and/or etching a dielectric or other film on the substrate. In one configuration, two pairs of the processing chambers, e.g., 108c-d and 108e-f, may be used to deposit dielectric material on the substrate, and the third pair of processing chambers, e.g., 108a-b, may be used to etch the deposited dielectric. In another configuration, all three pairs of chambers, e.g., 108a-f, may be configured to deposit stacks of alternating dielectric films on the substrate. Any one or more of the processes described may be carried out in chambers separated from the fabrication system shown in different embodiments. It will be appreciated that additional configurations of deposition, etching, annealing, and curing chambers for dielectric films are contemplated by system 100.

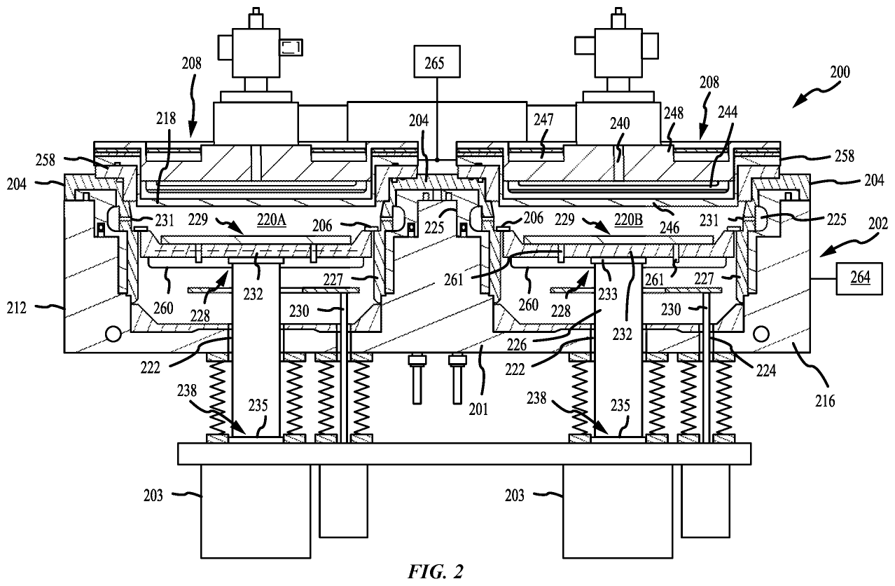

FIG. 2 shows a schematic cross-sectional view of an exemplary plasma system 200 according to some embodiments of the present technology. Plasma system 200 may illustrate a pair of processing chambers 108 that may be fitted in one or more of tandem sections 109 described above, and which may include lid stack components according to embodiments of the present technology, and as may be explained further below. The plasma system 200 generally may include a chamber body 202 having sidewalls 212, a bottom wall 216, and an interior sidewall 201 defining a pair of processing regions 220A and 220B. Each of the processing regions 220A-220B may be similarly configured, and may include identical components.

For example, processing region 220B, the components of which may also be included in processing region 220A, may include a pedestal 228 disposed in the processing region through a passage 222 formed in the bottom wall 216 in the plasma system 200. The pedestal 228 may provide a heater adapted to support a substrate 229 on an exposed surface of the pedestal, such as a body portion. The pedestal 228 may include heating elements 232, for example resistive heating elements, which may heat and control the substrate temperature at a desired process temperature. Pedestal 228 may also be heated by a remote heating element, such as a lamp assembly, or any other heating device.

The body of pedestal 228 may be coupled by a flange 233 to a stem 226. The stem 226 may electrically couple the pedestal 228 with a power outlet or power box 203. The power box 203 may include a drive system that controls the elevation and movement of the pedestal 228 within the processing region 220B. The stem 226 may also include electrical power interfaces to provide electrical power to the pedestal 228. The power box 203 may also include interfaces for electrical power and temperature indicators, such as a thermocouple interface. The stem 226 may include a base assembly 238 adapted to detachably couple with the power box 203. A circumferential ring 235 is shown above the power box 203. In some embodiments, the circumferential ring 235 may be a shoulder adapted as a mechanical stop or land configured to provide a mechanical interface between the base assembly 238 and the upper surface of the power box 203.

A rod 230 may be included through a passage 224 formed in the bottom wall 216 of the processing region 220B and may be utilized to position substrate lift pins 261 disposed through the body of pedestal 228. The substrate lift pins 261 may selectively space the substrate 229 from the pedestal to facilitate exchange of the substrate 229 with a robot utilized for transferring the substrate 229 into and out of the processing region 220B through a substrate transfer port 260.

A chamber lid 204 may be coupled with a top portion of the chamber body 202. The lid 204 may accommodate one or more precursor distribution systems 208 coupled thereto. The precursor distribution system 208 may include a precursor inlet passage 240 which may deliver reactant and cleaning precursors through a dual-channel showerhead 218 into the processing region 220B. The dual-channel showerhead 218 may include an annular base plate 248 having a blocker plate 244 disposed intermediate to a faceplate 246. A radio frequency (“RF”) source 265 may be coupled with the dual-channel showerhead 218, which may power the dual-channel showerhead 218 to facilitate generating a plasma region between the faceplate 246 of the dual-channel showerhead 218 and the pedestal 228. The dual-channel showerhead 218 and/or faceplate 246 may include one or more openings to permit the flow of precursors from the precursor distribution system 208 to the processing regions 220A and/or 220B. In some embodiments, the openings may include at least one of straight-shaped openings and conical-shaped openings. In some embodiments, the RF source may be coupled with other portions of the chamber body 202, such as the pedestal 228, to facilitate plasma generation. A dielectric isolator 258 may be disposed between the lid 204 and the dual-channel showerhead 218 to prevent conducting RF power to the lid 204. A shadow ring 206 may be disposed on the periphery of the pedestal 228 that engages the pedestal 228.

An optional cooling channel 247 may be formed in the annular base plate 248 of the precursor distribution system 208 to cool the annular base plate 248 during operation. A heat transfer fluid, such as water, ethylene glycol, a gas, or the like, may be circulated through the cooling channel 247 such that the base plate 248 may be maintained at a predefined temperature. A liner assembly 227 may be disposed within the processing region 220B in close proximity to the sidewalls 201, 212 of the chamber body 202 to prevent exposure of the sidewalls 201, 212 to the processing environment within the processing region 220B. The liner assembly 227 may include a circumferential pumping cavity 225, which may be coupled to a pumping system 264 configured to exhaust gases and byproducts from the processing region 220B and control the pressure within the processing region 220B. A plurality of exhaust ports 231 may be formed on the liner assembly 227. The exhaust ports 231 may be configured to allow the flow of gases from the processing region 220B to the circumferential pumping cavity 225 in a manner that promotes processing within the system 200.

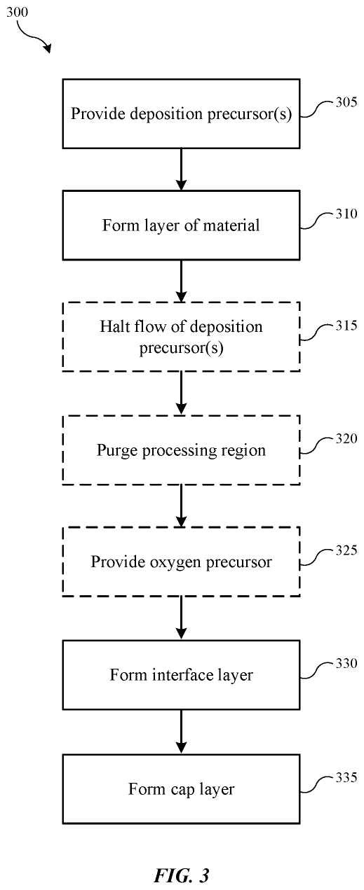

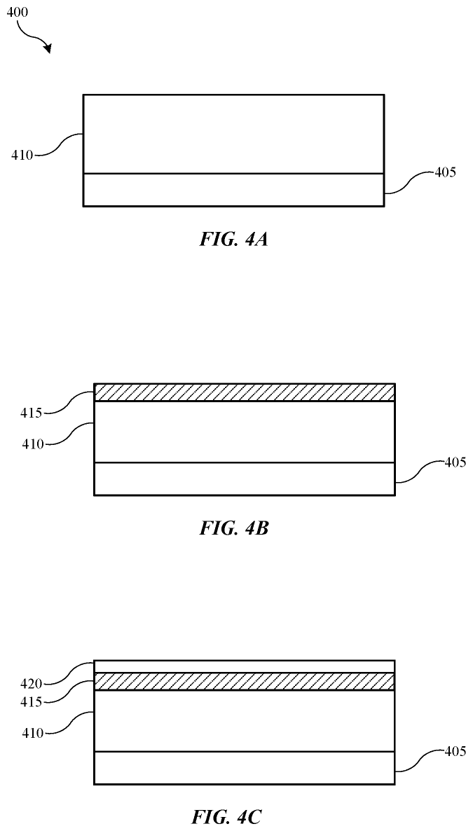

Although a plasma-processing chamber may be used for one or more aspects of film processing according to the present technology, in some embodiments, forming carbon films may not utilize a plasma-enhanced process. Utilizing plasma may limit conformality of the film produced by further releasing carbon from precursors, and which may limit carbon incorporation in the films produced by allowing the carbon to recombine with other radical species and flow from the chamber. The present technology may at least form the film without plasma generation in some embodiments. FIG. 3 shows operations of an exemplary method 300 of semiconductor processing according to some embodiments of the present technology. The method may be performed in a variety of processing chambers, including the semiconductor processing system 200 described above, as well as any other chamber in which plasma deposition may be performed. Method 300 may include a number of optional operations, which may or may not be specifically associated with some embodiments of methods according to the present technology. It is to be understood that method 300 may be performed on any number of semiconductor structures or substrates, including exemplary structure 400 or substrate 405 as illustrated in FIGS. 4A-4C on which layers of material may be formed. It is to be understood that FIGS. 4A-4C illustrate only partial schematic views, and a substrate may contain any number of structural sections having aspects as illustrated in the figures, as well as alternative structural aspects that may still benefit from operations of the present technology.

Method 300 may include a number of optional operations as illustrated, which may or may not be specifically associated with some embodiments of methods according to the present technology. For example, many of the operations are described in order to provide a broader scope of the structural formation, but are not critical to the technology, or may be performed by alternative methodology as will be discussed further below. As previously discussed, method 300 may describe operations shown schematically in FIGS. 4A-4C, the illustrations of which will be described in conjunction with the operations of method 300.

Prior to the first operation of the method 300, the substrate 405 may be processed in one or more ways before being placed within a processing region of a semiconductor processing system in which method 300 may be performed. Some or all of the operations may be performed in chambers or system tools as previously described, or may be performed in different chambers on the same system tool, which may include the semiconductor processing chamber in which the operations of method 300 may be performed.

The methods may include providing one or more deposition precursors to a processing region of a semiconductor processing chamber at operation 305. Substrate 405 may be disposed within the processing region of the semiconductor processing chamber. Substrate 405 may have a substantially planar surface or an uneven surface in embodiments. The substrate may be a material such as crystalline silicon, silicon oxide, strained silicon, silicon germanium, doped or undoped polysilicon, doped or undoped silicon wafers, patterned or non-patterned wafers, silicon on insulator, carbon doped silicon oxides, silicon nitride, doped silicon, germanium, gallium arsenide, or sapphire. The substrate 405 may have various dimensions, such as 200 mm or 300 mm diameter wafers, as well as rectangular or square panels.

The one or more deposition precursors may include a silicon-containing precursor. Silicon-containing precursors that may be used in deposition may be or include any number of silicon-containing precursors. The silicon-containing precursor may be any conventional semiconductor processing silicon compound for forming a silicon-containing material. For example, the silicon-containing precursor may be a ring type precursor, a linear precursor, a Si O—Si precursor, or a Si—C—Si precursor. Exemplary ring type precursors may include, but are not limited to, octamethylcyclotetrasiloxane, 2,4,6,8-Tetramethyl-2,4,6,8-tetravinylcyclotetrasiloxane, or 2,4,6,8-Tetramethylcyclotetrasiloxane. Exemplary linear precursors may include, but are not limited to, dimethyldimethoxysilane, ethoxydimethylsilane, isobutylmethyldimethoxysilane, or vinylmethyldimethoxysilane. Exemplary Si—O—Si precursors may include, but are not limited to, 1,1,3,3-Tetramethyl-1,3-dimethoxydisiloxane or 1,3-Dimethyl-1,1,3,3-tetramethoxydisiloxane. Exemplary Si—C—Si precursors may include, but are not limited to, methoxy(dimethyl)silylmethane or methyl(dimethoxy)silylmethane.

A flow rate of the silicon-containing precursor to the processing region of the semiconductor processing chamber may be less than or about 2,500 mg/min, and may be less than or about 2,250 mg/min, less than or about 2,000 mg/min, less than or about 1,750 mg/min, less than or about 1,500 mg/min, less than or about 1,400 mg/min, less than or about 1,300 mg/min, less than or about 1,200 mg/min, less than or about 1,100 mg/min, less than or about 1,000 mg/min, less than or about 900 mg/min, less than or about 800 mg/min, less than or about 700 mg/min, less than or about 600 mg/min, less than or about 500 mg/min, less than or about 400 mg/min, less than or about 300 mg/min, less than or about 200 mg/min, or lower.

In addition to the silicon-containing precursor, an oxygen-containing precursor may also be provided to the processing region of a semiconductor processing chamber. A flow rate of the oxygen-containing precursor to the processing region of the semiconductor processing chamber may be less than or about 1,000 sccm, and may be less than or about 900 sccm, less than or about 800 sccm, less than or about 700 sccm, less than or about 600 sccm, less than or about 500 sccm, less than or about 450 sccm, less than or about 400 sccm, less than or about 350 sccm, less than or about 300 sccm, less than or about 250 sccm, less than or about 200 sccm, less than or about 150 sccm, less than or about 100 sccm, or less. In embodiments, the oxygen-containing precursor may be or include molecular oxygen (O₂).

In some embodiments, additional precursors may be provided in addition to the silicon-containing precursor and, if present, the oxygen-containing precursor. For example, the deposition precursors may also include one or more carrier gases such as helium (He), nitrogen (N₂), and argon (Ar). Although the one or more carrier gases may be delivered with other deposition precursors, the carrier gases may be considered inert gases that do not react to form part of the as-deposited low dielectric constant material 410.

At operation 310, the method 300 may include forming a low dielectric constant material 410. The low dielectric constant material 410 may be formed overlying the substrate 405. The low dielectric constant material 410 may include, but is not limited to oxide materials, such as silicon oxide, or doped oxides with fluorine, carbon, or other low-k materials that may be used in processing. In embodiments, the low dielectric constant material may be characterized by Si—O—Si bonding. The low dielectric constant material may be characterized by a dielectric constant of less than or about 6.0, less than or about 5.5, less than or about 5.0, less than or about 4.5, less than or about 4.0, less than or about 3.5, less than or about 3.0, less than or about 2.7, less than or about 2.5, less than or about 2.3, or less.

The low dielectric constant material may be formed through various deposition methods, such as chemical vapor deposition, plasma-enhanced chemical vapor deposition, atomic layer deposition, or any other deposition method. In embodiments, the layer of low dielectric constant material may be formed through plasma-enhanced chemical vapor deposition. The plasma may be formed at a plasma power of less than or about 1,500 W. The plasma may be formed at a plasma power of less than or about 1,400 W, less than or about 1,300 W, less than or about 1,200 W, less than or about 1,100 W, less than or about 1,000 W, less than or about 900 W, less than or about 800 W, less than or about 700 W, less than or about 600 W, less than or about 500 W, less than or about 400 W, less than or about 300 W, or lower. In forming the layer of low dielectric constant material 410 through plasma-enhanced chemical vapor deposition, the material may contain a high amount of methyl groups (—CH₃ groups). The methyl groups may reduce the adhesion between the low dielectric constant material 410 and subsequently materials formed on the low dielectric constant material 410, such as a cap layer. Accordingly, the method 300 may include a post-deposition treatment to increase the adhesion between the low dielectric constant material 410 and subsequently materials formed on the low dielectric constant material 410.

A temperature within the semiconductor processing chamber may be maintained at less than or about 550° C. while forming the layer of low dielectric constant material 410. For example, temperature within the semiconductor processing chamber may be maintained at less than or about 525° C. while forming the layer of material, such as less than or about 500° C., less than or about 475° C., less than or about 450° C., less than or about 425° C., less than or about 400° C., less than or about 375° C., less than or about 350° C., less than or about 325° C., less than or about 300° C., less than or about 275° C., less than or about 250° C., less than or about 225° C., or lower.

A pressure within the semiconductor processing chamber may be maintained at less than or about 100 Torr while forming the layer of low dielectric constant material 410. For example, pressure within the semiconductor processing chamber may be maintained at less than or about 90 Torr while forming the layer of material, such as less than or about 80 Torr, less than or about 70 Torr, less than or about 60 Torr, less than or about 50 Torr, less than or about 40 Torr, less than or about 30 Torr, less than or about 20 Torr, less than or about 15 Torr, less than or about 12.5 Torr, less than or about 10 Torr, less than or about 9 Torr, less than or about 8 Torr, or lower.

At optional operation 315, the method 300 may include reducing or halting a flow of the deposition precursors, such as the silicon-containing precursor, the oxygen-containing precursor, and/or any carrier gases or inert precursors. In some embodiments, the method 300 may alternatively include reducing the flow of the deposition precursors. For example, the flow rate of the silicon-containing precursor may be reduced to less than or about 100 mg/min, less than or about 90 mg/min, less than or about 80 mg/min, less than or about 70 mg/min, less than or about 60 mg/min, less than or about 50 mg/min, less than or about 40 mg/min, less than or about 30 mg/min, less than or about 20 mg/min, less than or about 10 mg/min, or less. Reducing the flow rate of the silicon-containing precursor may reduce the amount of deposition occurring and allow the existing layer of low dielectric constant material 410 to be treated.

Simultaneous to or subsequent to reducing or halting the flow of the deposition precursors, the processing region of the semiconductor processing chamber may be purged at optional operation 320. Accordingly, a flow rate of the carrier gas and/or inert gas may be maintained in order to purge the processing region of the one or more deposition precursors. However, it is contemplated that the flow rate of the carrier gas and/or inert gas may be maintained and/or reduced. During the purge, a plasma power may be provided. The plasma power may increase the bombardment of the carrier gas and/or inert gas with the deposited low dielectric constant material 410. The bombardment may densify the layer of low dielectric constant material 410 while purging the processing region of the one or more deposition precursors. In embodiments, the plasma power at operations 315-320 may be reduced from the plasma power level maintained during the deposition to reduce the bombardment of the carrier gas and prevent any sputtering or damage to the film. For example, the plasma power at operations 315-320 may be maintained at less than or about 700 W, less than or about 600 W, less than or about 500 W, less than or about 400 W, less than or about 300 W, less than or about 200 W, less than or about 100 W, less than or about 75 W, or less.

At optional operation 325, the method 300 may include providing an oxygen-containing precursor to the processing region. That is, in some embodiments, the oxygen-containing precursor may be provided while purging the processing region of the other deposition precursors. By providing the oxygen-containing precursor while purging the processing region, an upper surface of the layer of low dielectric constant material 410 opposite the substrate 405 may be treated with the oxygen-containing precursor and/or oxygen-containing plasma effluents. The oxygen-containing precursor and/or oxygen-containing plasma effluents may reduce the amount of methyl groups at the upper surface of the layer of low dielectric constant material 410 and increase the oxygen concentration in the layer of low dielectric constant material 410, forming an interface layer 415 on the layer of low dielectric constant material at operation 330 as shown in FIG. 4B. The interface layer 415 may be an upper portion of the low dielectric constant material 410. It is contemplated that treating the terminal methyl groups at the upper surface of the layer of low dielectric constant material 410 may replace the methyl groups with oxygen-containing groups, such as —CH₂OH, —CHO, and/or —COOH, which may increase adhesion with subsequently formed materials. The oxygen-containing groups, such as —CH₂OH, —CHO, and/or —COOH, may more readily interface and/or bond with a cap layer formed over the low dielectric constant material 410, as further described below.

In other embodiments, the method 300 may not include purging the processing region at optional operation 320 and/or reducing or halting a flow of the deposition precursors at optional operation 315. Instead, one or more of the deposition precursors, such as the silicon-containing precursor and/or the oxygen-containing precursor, may be continuously provided. However, it is contemplated that the flow rates of one or more deposition precursors may be modified. For example, the flow rate of the silicon-containing precursor may be maintained or reduced while the flow rate of the oxygen-containing precursor may be maintained or increased. When the silicon-containing precursor flow rate is reduced, the layer of low dielectric constant material 410 may be treated similarly to providing the oxygen-containing precursor while purging the processing region as previously discussed, thereby forming the interface layer 415 on the layer of low dielectric constant material 410. Specifically, the layer of low dielectric constant material 410 may be treated with the oxygen-containing precursor and/or oxygen-containing plasma effluents to reduce the amount of methyl groups and/or increase the oxygen concentration at the upper surface of the layer of low dielectric constant material 410. Instead, if the silicon-containing precursor flow rate is maintained or only reduced by a small amount, an oxygen-rich silicon oxide material may be formed as the interface layer 415 on the layer of low dielectric constant material 410. The oxygen-rich material may result in better adhesion with subsequently formed oxygen-containing materials, such as oxygen-containing cap layers.

The operations of method 300, such as operations 310 and 330, may be formed at the same or similar process conditions. For example, the temperature and/or pressure may be maintained for both the formation of the layer of low dielectric constant material 410 and the formation of the interface layer 415. Conversely, the temperature and/or pressure may be modified or adjusted between the formation of layer of low dielectric constant material 410 and the formation of the interface layer 415. However, in embodiments, the plasma power may be reduced from a first plasma power level while forming the layer of low dielectric constant material 410 to a second plasma power level lower than the first plasma power level while forming the interface layer 415 as previously discussed. As previously discussed, the reduction in the plasma power level may preserve the layer of low dielectric constant material 410 and not damage the material.

As shown in FIG. 4C, subsequent to forming the interface layer 415, a cap layer 420 may be formed at operation 335. The cap layer 420 may be an oxide cap layer, such as a layer formed from a silicon-and-oxygen containing material (e.g., tetraethyl orthosilicate or TEOS). The cap layer 420 may also be an anti-reflective coating, such as a dielectric anti-reflective coating. The anti-reflective coating may be a silicon oxide film. The anti-reflective coating may additionally include carbon and/or nitrogen. In conventional operations, an interface layer may not be formed and adhesion issues between the two films may result in delamination of the cap layer from the layer of low dielectric constant material. For example, without an interface layer, the adhesion value between the layer of low dielectric constant material and the cap layer may be less than 3.0 J/m². However, by forming the interface layer 415 according to embodiments of the present disclosure, the adhesion value between the layer of low dielectric constant material 410 and the cap layer 420 via the interface layer 415 may be greater than or about 3.0 J/m². The adhesion layer may be greater due to the oxygen concentration of in the interface layer 415, which may more readily interact with oxygen in the cap layer 420. In embodiments, the adhesion value may be greater than or about 3.5 J/m², greater than or about 4.0 J/m², greater than or about 4.5 J/m², greater than or about 5.0 J/m², greater than or about 5.5 J/m², greater than or about 6.0 J/m², or more. These adhesion values, such as an adhesion value greater than 3.0 J/m² may be indicative of sufficient adhesion between the layer of low dielectric constant material 410 and the cap layer 420, such that minimal or zero delamination may occur during subsequent processing.

FIG. 4C shows a final structure 400 that may be formed according to method 300. The structure 400 may include any of the features previously discussed with regard to method 300. For example, the structure 400 may include a semiconductor substrate 405. The structure 400 may include a layer of low dielectric constant material 410 disposed on the semiconductor substrate 405. The structure 400 may include a cap layer 420 formed above the layer of low dielectric constant material 410. The structure 400 may include an interface layer 415 disposed between the layer of low dielectric constant material 410 and the cap layer 420. As discussed, an adhesion value between the layer of low dielectric constant material 410 and the cap layer 420 may be greater than or about 4.0 J/m².

In embodiments, the interface layer 415 may be a portion of the layer of low dielectric constant material 410. For example, an upper portion of the low dielectric constant material 410 may be treated to form the interface layer 415. Alternatively, the interface layer 415 may be an oxygen-rich material distinctly formed over the layer of low dielectric constant material 410. In embodiments, the interface layer 415 may be characterized by a lower methyl incorporation and/or a higher oxygen concentration than the layer of low dielectric constant material 410.

By utilizing one or more of the described processes, controlled and discrete formation of materials may be provided, leading to improved layers of material and, therefore, structures 400 may be afforded, where one layer, such as the layer of low dielectric constant material 410 may be treated to form the interface layer 415 that increases adhesion between the layer of low dielectric constant material 410 and the cap layer 420, all while in the same chamber without exposing the structures to atmosphere. Consequently, improved structures may be afforded by the present technology, which may produce structures with improved adhesion between low dielectric constant materials and cap layers over conventional technologies.

In the preceding description, for the purposes of explanation, numerous details have been set forth in order to provide an understanding of various embodiments of the present technology. It will be apparent to one skilled in the art, however, that certain embodiments may be practiced without some of these details, or with additional details.

Having disclosed several embodiments, it will be recognized by those of skill in the art that various modifications, alternative constructions, and equivalents may be used without departing from the spirit of the embodiments. Additionally, a number of well-known processes and elements have not been described in order to avoid unnecessarily obscuring the present technology. Accordingly, the above description should not be taken as limiting the scope of the technology. Additionally, methods or processes may be described as sequential or in steps, but it is to be understood that the operations may be performed concurrently, or in different orders than listed.

Where a range of values is provided, it is understood that each intervening value, to the smallest fraction of the unit of the lower limit, unless the context clearly dictates otherwise, between the upper and lower limits of that range is also specifically disclosed. Any narrower range between any stated values or unstated intervening values in a stated range and any other stated or intervening value in that stated range is encompassed. The upper and lower limits of those smaller ranges may independently be included or excluded in the range, and each range where either, neither, or both limits are included in the smaller ranges is also encompassed within the technology, subject to any specifically excluded limit in the stated range. Where the stated range includes one or both of the limits, ranges excluding either or both of those included limits are also included.

As used herein and in the appended claims, the singular forms “a”, “an”, and “the” include plural references unless the context clearly dictates otherwise. Thus, for example, reference to “a deposition precursor” includes a plurality of such precursors, and reference to “the layer of low dielectric constant material” includes reference to one or more layers of low dielectric constant material and equivalents thereof known to those skilled in the art, and so forth.

Also, the words “comprise(s)”, “comprising”, “contain(s)”, “containing”, “include(s)”, and “including”, when used in this specification and in the following claims, are intended to specify the presence of stated features, integers, components, or operations, but they do not preclude the presence or addition of one or more other features, integers, components, operations, acts, or groups.

1. A semiconductor processing method comprising:
providing one or more deposition precursors to a processing region of a semiconductor processing chamber, wherein a semiconductor substrate is positioned within the processing region;
forming a layer of low dielectric constant material on the semiconductor substrate;
forming an interface layer on the layer of low dielectric constant material; and
forming a cap layer on the interface layer.

2. The semiconductor processing method of claim 1, wherein the semiconductor substrate is maintained at a temperature less than or about 550° C. during the semiconductor processing method.

3. The semiconductor processing method of claim 1, further comprising:
purging the processing region of the one or more deposition precursors, wherein a plasma power is maintained at less than or about 750 W while purging the processing region.

4. The semiconductor processing method of claim 1, further comprising:
halting a flow of the one or more deposition precursors prior to forming the interface layer.

5. The semiconductor processing method of claim 1, further comprising:
providing an oxygen-containing precursor to the processing region prior to forming the interface layer.

6. The semiconductor processing method of claim 5, wherein a flow rate of the oxygen-containing precursor is less than or about 750 sccm.

7. The semiconductor processing method of claim 1, further comprising:
densifying the layer of low dielectric constant material while purging the processing region of the one or more deposition precursors.

8. The semiconductor processing method of claim 1, wherein an adhesion value between the layer of low dielectric constant material and the cap layer is greater than or about 3.0 J/m².

9. A semiconductor processing method comprising:
forming a layer of low dielectric constant material on a semiconductor substrate housed in a processing region of a semiconductor processing chamber, wherein a plasma power is maintained at a first plasma power level while forming the layer of low dielectric constant material;
purging the processing region, wherein the plasma power is maintained at a second plasma power level while purging the processing region, and wherein the second plasma power level is less than or equal to the first plasma power level;
forming an interface layer on the layer of low dielectric constant material; and
forming a cap layer on the interface layer.

10. The semiconductor processing method of claim 9, wherein the semiconductor substrate comprises silicon.

11. The semiconductor processing method of claim 9, wherein the layer of low dielectric constant material is formed through plasma-enhanced chemical vapor deposition.

12. The semiconductor processing method of claim 9, wherein the interface layer is characterized by a lower methyl incorporation than the layer of low dielectric constant material.

13. The semiconductor processing method of claim 9, further comprising:
providing molecular oxygen to the processing region while purging the processing region.

14. The semiconductor processing method of claim 9, further comprising:
reducing a flow rate of one or more precursors used to form the layer of low dielectric constant material prior to purging the processing region.

15. The semiconductor processing method of claim 9, wherein a temperature and a pressure in the processing region while forming the layer of low dielectric constant material are maintained while forming the interface layer.

16. The semiconductor processing method of claim 9, further comprising:
reducing a flow rate of a carrier gas prior to purging the processing region.

17. A semiconductor structure comprising:
a semiconductor substrate;
a layer of low dielectric constant material disposed on the semiconductor substrate;
a cap layer formed above the layer of low dielectric constant material; and
an interface layer disposed between the layer of low dielectric constant material and the cap layer, wherein an adhesion value between the layer of low dielectric constant material and the cap layer is greater than or about 4.0 J/m².

18. The semiconductor structure of claim 17, wherein the interface layer is a portion of the layer of low dielectric constant material.

19. The semiconductor structure of claim 17, wherein the interface layer is characterized by a lower methyl incorporation than the layer of low dielectric constant material.

20. The semiconductor structure of claim 17, wherein the interface layer is characterized by a higher oxygen concentration than the layer of low dielectric constant material.
